(19) United States
(12) Patent Application Publication
(10) Pub. No.: US 2018/0057933 A1
(43) Pub. Date: Mar. 1, 2018

(54) METHOD FOR PRODUCING GRAPHENE

(71) Applicant: TOKYO ELECTRON LIMITED, Tokyo (JP)

(72) Inventors: Ryota IFUKU, Nirasaki City (JP); Takashi MATSUMOTO, Nirasaki City (JP)

(21) Appl. No.: 15/689,307

(22) Filed: Aug. 29, 2017

(30) Foreign Application Priority Data
Sep. 1, 2016 (JP) 2016-171297

(51) Int. Cl. C23C 16/26; C23C 14/06; C23C 14/02; C23C 16/02; C01B 32/186

(52) U.S. Cl. CPC C23C 16/26; C23C 14/0605; H01L 23/53276; C23C 16/0227; C01B 32/186; C23C 14/021

(57) ABSTRACT

There is provided a method for producing graphene which includes a first growth step of supplying a carbon-containing gas into a chamber in which a metal catalyst is disposed to grow graphene on a surface of the metal catalyst, an activation step of supplying a process gas containing an oxygen gas or a hydrogen gas into the chamber in which the metal catalyst having the graphene grown on the surface thereof is disposed to reactivate the metal catalyst, and a second growth step of supplying the carbon-containing gas into the chamber in which the reactivated metal catalyst is disposed to regrow the graphene on the surface of the metal catalyst.

### CROSS-REFERENCE TO RELATED APPLICATION

This application is based upon and claims the benefit of priority from Japanese Patent Application No. 2016-171297, filed on Sep. 1, 2016, the entire contents of which are incorporated herein by reference.

### TECHNICAL FIELD

Various aspects and embodiments of the present disclosure generally relate to a method for producing graphene.

### BACKGROUND

It has been known that graphene has a two-dimensional structure in which six-membered rings of carbon atoms are connected in a planar shape and has very excellent electrical and thermal properties. For this reason, the graphene has attracted attention as a material of a fine wiring used for a three-dimensional structure memory or the like. Further, there is known a technique for forming graphene by CVD (Chemical Vapor Deposition). In this technique, a carbon-containing gas is supplied to the surface of a metal catalyst. Carbon solid-solved in the metal catalyst is precipitated on the surface of the metal catalyst, whereby the graphene is formed.

Incidentally, when using the graphene as a wiring material, it is preferable that the grain size of the graphene which is a crystal is large. This makes it possible to easily form a wiring of an arbitrary shape with high conductivity. According to the conventional graphene producing method, the graphene grows on the surface of a metal catalyst due to precipitation of carbon. However, the growth of the graphene slows down as time elapses, and the growth of the graphene eventually stops. Therefore, it is difficult to produce graphene having a large grain size.

### SUMMARY

Some embodiments of the present disclosure provide a method of producing graphene having a large grain size.

According to one embodiment of the present disclosure, there is provided a method for producing graphene. The method includes a first growth step of supplying a carbon-containing gas into a chamber in which a metal catalyst is disposed to grow graphene on a surface of the metal catalyst, an activation step of supplying a process gas containing an oxygen gas or a hydrogen gas into the chamber in which the metal catalyst having the graphene grown on the surface thereof is disposed to reactivate the metal catalyst, and a second growth step of supplying the carbon-containing gas into the chamber in which the reactivated metal catalyst is disposed to regrow the graphene on the surface of the metal catalyst.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a system configuration diagram showing an example of a configuration of a graphene producing system.

FIG. 2 is a sectional view showing an example of a configuration of each processing module.

FIG. 3 is a flowchart showing an example of a graphene producing process.

FIGS. 4A to 4E are schematic diagrams showing an example of a graphene producing process.

FIG. 5 is a set of SEM photographs showing an example of a change in the grain size of a crystal of a graphene.

FIG. 6 is an SEM photograph showing an example of the surface of graphene after a first growth process.

FIGS. 7A and 7B are diagrams showing examples of a distribution of the Raman spectrum,

FIG. 8 is an SEM photograph showing an example of a surface of a metal catalyst after a third heat treatment.

FIGS. 9A and 9B are diagrams showing examples of a distribution of the Raman spectrum on a surface of a metal catalyst after a third heat treatment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The graphene producing method disclosed herein include, in one embodiment, a first growth step, an activation step, and a second growth step. In the first growth step, a carbon-containing gas is supplied into a chamber in which a metal catalyst is disposed, to make the graphene grow on a surface of the metal catalyst. In the activation step, a process gas containing an oxygen gas or a hydrogen gas is supplied into the chamber in which the metal catalyst having the graphene grown on the surface thereof is disposed, thereby reactivating the metal catalyst. In the second growth step, a carbon-containing gas is supplied into the chamber in which the reactivated metal catalyst is disposed, to make the graphene regrow on the surface of the metal catalyst.

Further, in one embodiment of the disclosed graphene producing method, a cleaning step of cleaning the surface of the metal catalyst with a process gas containing a hydrogen gas may be further included between the activation step and the second growth step.

Further, in one embodiment of the disclosed graphene producing method, the metal catalyst may be a transition metal or an alloy containing two or more transition metals.

Further, in one embodiment of the disclosed graphene producing method, the metal catalyst may be Ni, Co, Fe, Cu, W, or an alloy containing two or more thereof.

Further, in one embodiment of the disclosed graphene producing method, the activation step may be performed by using a process gas containing an oxygen gas and an inert gas under a condition in which the temperature of the metal catalyst falls within a temperature range of 200 degrees C. or higher and 400 degrees C. or lower.

Further, in one embodiment of the disclosed graphene producing method, the activation step and the second growth step may be performed alternately and repeatedly.

Hereinafter, an embodiment of a graphene producing method disclosed herein will be described in detail with reference to the drawings. The graphene producing method disclosed by the embodiment of the present disclosure is not limited thereto.

### [Graphene Production System 10]

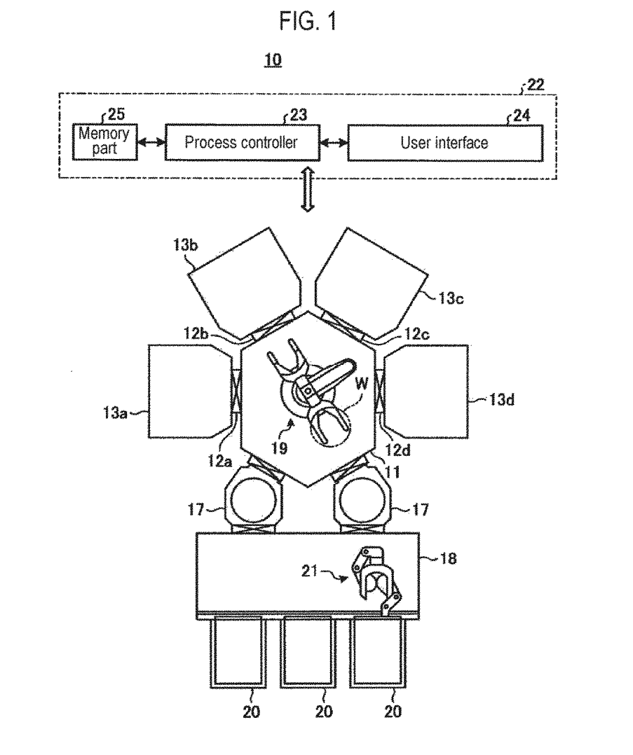

FIG. 1 is a system configuration diagram showing an example of a configuration of a graphene producing system 10. As shown in FIG. 1, for example, the graphene producing system 10 includes a depressurized transfer module 11 having a substantially hexagonal shape in a plan view. The graphene producing system 10 further includes a base film forming module 13a, a first heat treatment module 13b, a graphene producing module 13c and a second heat treatment module 13d, which are radially arranged around the reduced pressure transfer module 11. In the following description, the base film forming module 13a, the first heat treatment module 13b, the graphene producing module 13c and the second heat treatment module 13d will be simply referred to as a processing module 13 when they are collectively being referred to without distinguishing them.

The interior of the depressurized transfer module 11 is depressurized to a predetermined degree of vacuum. The depressurized transfer module 11 is connected to the base film forming module 13a via a gate valve 12a, connected to the first heat treatment module 13b via a gate valve 12b, connected to the graphene producing module 13c via a gate valve 12c and connected to the second heat treatment module 13d via a gate valve 12d. In the following description, the gate valves 12a to 12d will be simply referred to as gate valve 12 when they are collectively being referred to without distinguishing them.

The interior of the base film forming module 13a is depressurized to a predetermined degree of vacuum and is configured to form a metal catalyst to be described later as a base film on a wafer W such as a silicon substrate or the like by PVD (Physical Vapor Deposition) or CVD. The first heat treatment module 13b thermally treats the wafer W on which the metal catalyst is formed. The graphene producing module 13c produces graphene on the metal catalyst formed on the thermally-treated wafer W. The second heat treatment module 13d thermally treats the wafer W on which the graphene is formed. The first heat treatment module 13b and the second heat treatment module 13d may be realized by one processing module 13.

Load lock modules 17 are connected to the depressurized transfer module 11. In the graphene producing system 10 illustrated in FIG. 1, two load lock modules 17 are connected to the depressurized transfer module 11. A transfer robot 19 is provided in the depressurized transfer module 11. The transfer robot 19 transfers the wafer W between the load lock modules 17 and the processing modules 13 and between the respective processing modules 13.

A loader module 18 is connected to the respective load lock modules 17. A transfer robot 21 is provided inside the loader module 18. The transfer robot 21 takes out an unprocessed wafer W from a carrier 20 accommodating a plurality of wafers W and transfers the unprocessed wafer W into each of the load lock modules 17. Further, the transfer robot 21 takes out the processed wafer W, on which the graphene is formed, from each of the load lock modules 17 and transfers the processed wafer W into the carrier 20.

In the present embodiment, each of the base film forming module 13a, the first heat treatment module 13b, the graphene producing module 13c and the second heat treatment module 13d is configured as separate processing modules 13. However, the base film forming module 13a, the first heat treatment module 13b, the graphene producing module 13c and the second heat treatment module 13d may be realized by one processing module 13.

The graphene producing system 10 includes a control part 22 that controls the operations of the respective elements. The control part 22 controls the operations of the respective elements of the graphene producing system 10, for example, the respective processing modules 13, the transfer robot 19, the transfer robot 21, and the like. The control part 22 includes a process controller 23 having a microprocessor (computer), a user interface 24, and a memory part 25.

The user interface 24 includes a keyboard or a touch panel to which a user inputs a command to control the operations of the respective parts of the graphene producing system 10, a display for visualizing and displaying the operation status of each part of the graphene producing system 10, and the like. In the memory part 25, there are stored a control program (software) for realizing various processes executed in the respective parts of the graphene producing system 10 through the control of the process controller 23, a recipe in which data of processing conditions and the like are recorded, and the like.

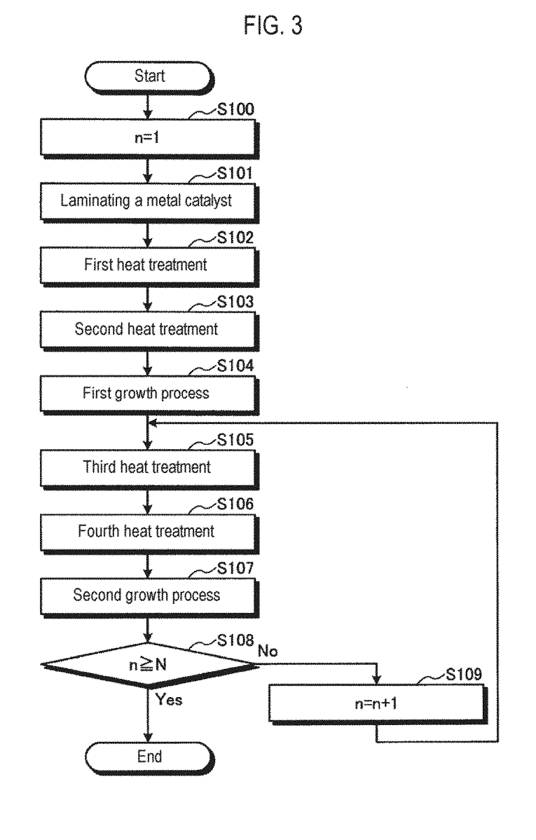

The process controller 23 reads out an arbitrary recipe from the memory part 25 and executes the arbitrary recipe in response to a command or the like inputted from the user interface 24. At this time, for example, a graphene producing process, which will be described later with reference to FIG. 3, is executed in the respective processing modules 13.

The control program or the recipe in which the data of processing conditions and the like are recorded may be stored in a portable recording medium readable by a computer. The process controller 23 may read out the control program, the data of processing conditions, or the like from the recording medium and may execute the same. As the recording medium, it may be possible to use, for example, a CD-ROM, a hard disk, a flexible disk, a flash memory, or the like. In addition, the recipe may be transmitted from another device via a communication line or the like.

### [Configuration of Each Processing Module 13]

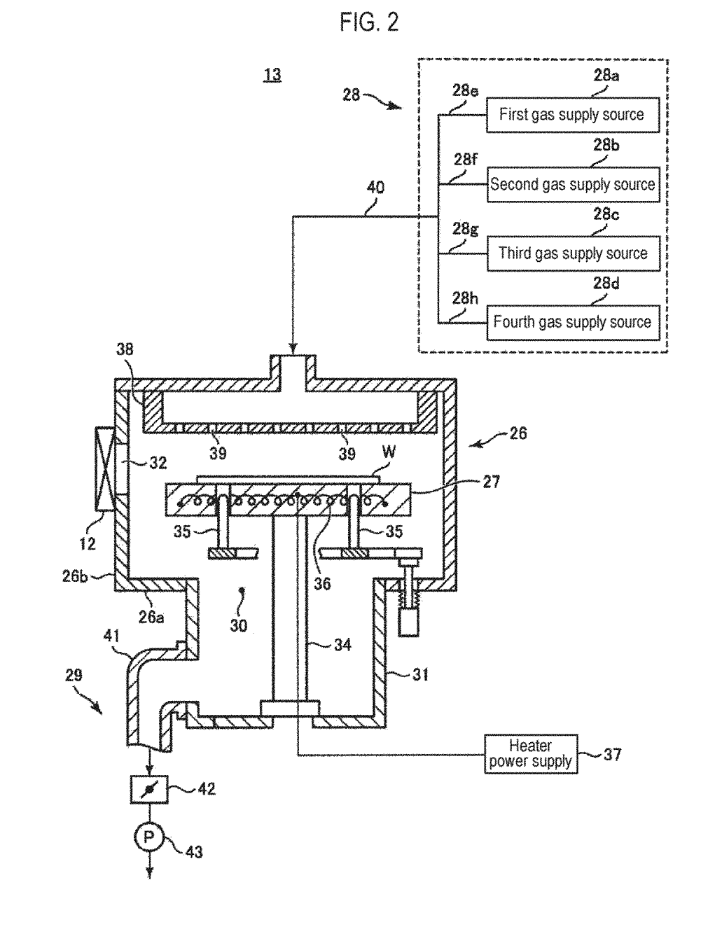

FIG. 2 is a sectional view showing an example of the configuration of each processing module 13. The base film forming module 13a, the first heat treatment module 13b, the graphene producing module 13c and the second heat treatment module 13d have the same structure as the processing module 13 shown in FIG. 2. As shown in FIG. 2, for example, each processing module 13 includes a substantially cylindrical chamber 26 configured airtightly, a mounting table 27 provided inside the chamber 26 and configured to mount a wafer W thereon, a gas supply part 28 configured to supply a gas into the chamber 26, and an exhaust part 29 configured to exhaust the interior of the chamber 26.

A circular opening 30 is formed substantially at the center of a bottom wall 26a of the chamber 26. An exhaust chamber 31 communicating with the interior of the chamber 26 via the opening 30 and protruding downward is provided in the bottom wall 26a. An opening 32 for loading the wafer W into the chamber 26 and unloading the wafer W from the interior of the chamber 26 is formed in a side wall 26b of the chamber 26. In the opening 32, there is provided a gate valve 12 for opening and closing the opening 32. When the gate valve 12 is opened, the chamber 26 communicates with the depressurized transfer module 11 via the opening 32.

The mounting table 27 is made of, for example, ceramics such as aluminum nitride or the like and is supported by a support column 34 extending upward from a substantial center of the bottom of the exhaust chamber 31. Lift pins 35 for raising and lowering the wafer W is disposed inside the mounting table 27. The lifting pins 35 protrude from the surface of the mounting table 27 to thereby separate the wafer W from the mounting table 27.

A heater 36 is embedded in the mounting table 27. A heater power supply 37 is connected to the heater 36. The heater 36 generates heat using the electric power supplied from the heater power supply 37 and heats the wafer W mounted on the mounting table 27. In addition, a temperature sensor (not shown) such as a thermocouple or the like is provided on the mounting table 27. The temperature of the wafer W on the mounting table 27 is measured by the temperature sensor. The electric power supplied from the heater power supply 37 to the heater 36 is controlled so that the temperature of the wafer W falls within a predetermined range. In the following description, the temperature of the wafer W does not refer to the set temperature of the heater 36 but the temperature measured by the temperature sensor, unless specifically mentioned otherwise.

A shower plate 38 having a plurality of gas discharge holes 39 formed in the lower surface thereof is provided in the upper portion of the chamber 26. The shower plate 38 is connected to the gas supply part 28 via a gas supply path 40. The gas supplied from the gas supply part 28 is supplied into the shower plate 38 and is supplied from the respective gas discharge holes 39 in the lower surface of the shower plate 38 into the chamber 26 in a shower shape.

The gas supply part 28 includes a first gas supply source 28a, a second gas supply source 28b, a third gas supply source 28c, and a fourth gas supply source 28d. The first gas supply source 28a is configured to supply a first gas to the gas supply path 40 via a gas supply path 28e. The second gas supply source 28b is configured to supply a second gas to the gas supply path 40 via a gas supply path 28f. The third gas supply source 28c is configured to supply a third gas to the gas supply path 40 via a gas supply path 28g. The fourth gas supply source 28d is configured to supply a fourth gas to the gas supply path 40 via a gas supply path 28h. Flow controllers such as mass flow controllers or the like, valves, and the like are provided in the respective gas supply paths 28e to 28h.

In the case where the processing module 13 is the base film forming module 13a, the first gas is, for example, an organic metal compound gas such as a nickel amide compound gas or the like, the second gas is, for example, an inert gas such as argon (Ar) gas or the like, the third gas is, for example, an ammonia gas (NH₃), and the fourth gas is, for example, a hydrogen gas (H₂). As the inert gas, in addition to a rare gas such as an argon gas or the like, it may be possible to use a nitrogen (N₂) gas.

In the case where the processing module 13 is the first heat treatment module 13b, the first gas is, for example, a hydrogen gas, and the second gas is, for example, an inert gas such as an argon gas or the like. When the processing module 13 is the first heat treatment module 13b, the third gas supply source 28c and the fourth gas supply source 28d are not used.

In the case where the processing module 13 is the graphene producing module 13c, the first gas is, for example, a hydrogen gas, the second gas is, for example, an inert gas such as an argon gas or the like, and the third gas is, for example, a carbon-containing gas such as an acetylene gas (C₇H₇) or the like. As the carbon-containing gas used as the third gas, in addition to the acetylene gas, it may be possible to use, for example, a hydrocarbon gas such as ethylene (C₂H₄), methane (CH₄), ethane (C₂H₆), propane (C₃H₈), propylene (C₃H₆) or the like, a cyclic hydrocarbon gas such as benzene (C₆H₆), toluene (C₇H₈), ethylbenzene (C₈H₁₀), styrene (C₈H₈), cyclohexane (C₆H₁₂) or the like, and further alcohols such as methanol (CH₃OH), ethanol (C₂H₅OH) and the like. In addition, when the processing module 13 is the graphene producing module 13c, the fourth gas supply source 28d is not used.

When the processing module 13 is the second heat treatment module 13d, the first gas is, for example, a hydrogen gas, the second gas is, for example, an inert gas such as an argon gas or the like, and the third gas is, for example, an oxygen gas (O₂). Also, when the processing module 13 is the second heat treatment module 13d, the fourth gas supply source 28d is not used.

The exhaust part 29 includes an exhaust pipe 41 connected to an opening on the side surface of the exhaust chamber 31. A butterfly valve 42 and a vacuum pump 43 are connected to the exhaust pipe 41. The exhaust part 29 exhausts the gas existing inside the chamber 26 via the exhaust chamber 31 and the exhaust pipe 41 by operating the butterfly valve 42 and the vacuum pump 43. As such, the exhaust part 29 may depressurize the interior of the chamber 26 to a predetermined degree of vacuum.

### [Graphene Producing Process]

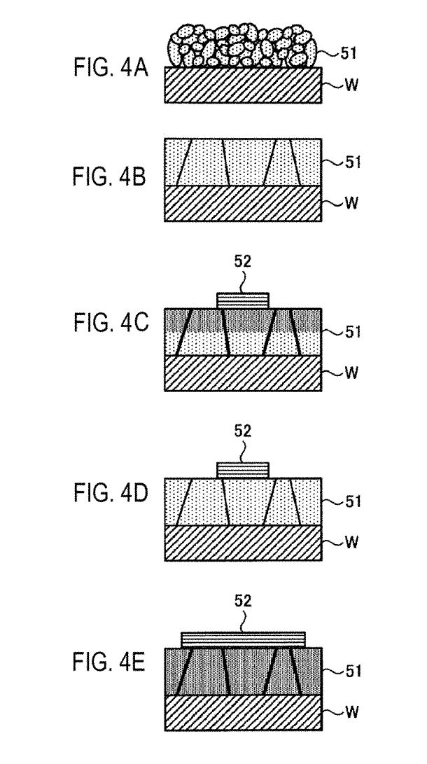

FIG. 3 is a flowchart showing an example of a graphene producing process. FIGS. 4A to 4E are schematic views showing an example of a graphene producing process. The graphene producing process shown in FIG. 3 is executed by the process controller 23.

First, the process controller 23 initializes a variable n for counting the number of repetitions to 1 (S100). Then, the process controller 23 controls the transfer robot 21 so as to transfer the unprocessed wafer W from the carrier 20 to the load lock module 17. Then, the process controller 23 opens the gate valve 12a of the base film forming module 13a, controls the transfer robot 19 so as to mount the unprocessed wafer W on the mounting table 27 in the base film forming module 13a, and closes the gate valve 12a.

Next, the process controller 23 controls the base film forming module 13a so as to laminate a metal catalyst 51 containing nickel (Ni) on the wafer W, for example, as shown in FIG. 4A (S101). More specifically, the process controller 23 controls the butterfly valve 42 and the vacuum pump 43 of the base film forming module 13a so as to depressurize the interior of the chamber 26 to a predetermined degree of vacuum. Then, the process controller 23 allows the nickel amide compound gas from the first gas supply source 28a, the argon gas from the second gas supply source 28b, the ammonia gas from the third gas supply source 28c and the hydrogen gas from the fourth gas supply source 28d to be supplied into the chamber 26 via the shower plate 38 at predetermined flow rates, respectively. Then, the process controller 23 controls the heater power supply 37 so as to set the temperature of the wafer W to a predetermined temperature. Thus, for example, as shown in FIG. 4A, the metal catalyst 51 is laminated on the wafer W. In the present embodiment, the process controller 23 controls the respective parts of the base film forming module 13a so that the metal catalyst 51 having a film thickness of, for example, 100 to 600 nm, is laminated on the wafer W.

Next, the process controller 23 opens the gate valve 12a of the base film forming module 13a and controls the transfer robot 19 so as to unload the wafer W, on which the metal catalyst 51 is laminated, from the base film forming module 13a. Then, the process controller 23 opens the gate valve 12b of the first heat treatment module 13b, controls the transfer robot 19 so as to mount the water W, on which the metal catalyst 51 is laminated, on the mounting table 27 in the first heat treatment module 13b, and closes the gate valve 12b.

Then, the process controller 23 controls the first heat treatment module 13b so as to execute a first heat treatment on the wafer W (S102). Specifically, the process controller 23 controls the butterfly valve 42 and the vacuum pump 43 of the first heat treatment module 13b so as to depressurize the interior of the chamber 26 to a predetermined degree of vacuum. Then, the process controller 23 supplies the hydrogen gas from the first gas supply source 28a and the argon gas from the second gas supply source 28b into the chamber 26 at predetermined flow rates, respectively, via the shower plate 38. Then, the process controller 23 controls the heater power supply 37 so as to set the temperature of the wafer W to a predetermined temperature. In step S102, the heat treatment is performed at two types of temperatures. Thus, as shown in FIG. 4B, for example, the grain size of a crystal of the metal catalyst 51 laminated on the wafer W is increased, and the flatness of the surface of the metal catalyst 51 is improved.

The first heat treatment in step S102 is performed, for example, under the following processing conditions. In the first heat treatment, heat treatments at the temperature and the treatment time shown in (1) and (2) are sequentially performed at a gas flow rate ratio and a pressure of the flow ratio indicated below.

Gas flow rate ratio: Ar/H₂=1000,/1000 sccm

Pressure inside chamber 26: 1 Ton

(1) Temperature of wafer W: 300 degrees C., treatment time: 10 minutes

(2) Temperature of wafer W: 650 degrees C., treatment time: 10 minutes

Next, the process controller 23 opens the gate valve 12b of the first heat treatment module 13b and controls the transfer robot 19 so as to unload the wafer W subjected to the first heat treatment from the first heat treatment module 13b. Then, the process controller 23 opens the gate valve 12c of the graphene producing module 13c, controls the transfer robot 19 so as to mount the wafer W, on which the first heat treatment is performed, on the mounting table 27 in the graphene producing module 13c, and closes the gate valve 12c.

Then, the process controller 23 controls the graphene producing module 13c so as to execute a second heat treatment on the wafer W (S103). More specifically, the process controller 23 controls the butterfly valve 42 and the vacuum pump 43 of the graphene producing module 13c so as to depressurize the interior of the chamber 26 to a predetermined degree of vacuum. Then, the process controller 23 supplies the hydrogen gas from the first gas supply source 28a and the argon gas from the second gas supply source 28b into the chamber 26 at predetermined flow rates, respectively, via the shower plate 38. Then, the process controller 23 controls the heater power supply 37 so as to set the temperature of the wafer W to a predetermined temperature. As a result, when the wafer W is transferred through the depressurized transfer module 11, the surface of the metal catalyst 51, which has been oxidized by the air in the depressurized transfer module, 11 is reduced.

The second heat treatment in step S103 is performed, for example, under the following processing conditions.

Gas flow rate ratio: Ar/FL=1000/1000 sccm

Pressure inside chamber 26: 1 Torr

Temperature of wafer W: 500 degrees C.

Treatment time: 5 minutes

Next, the process controller 23 controls the graphene producing module 13c so as to execute a first growth process for growing graphene on the surface of the metal catalyst 51 on the wafer W (S104). More specifically, the process controller 23 controls the butterfly valve 42 and the vacuum pump 43 of the graphene producing module 13c so as to depressurize the interior of the chamber 26 to a predetermined degree of vacuum. Then, the process controller 23 supplies the hydrogen gas from the first gas supply source 28a, the argon gas from the second gas supply source 28b and the acetylene gas from the third gas supply source 28c into the chamber 26 via the shower plate 38 at predetermined flow rates, respectively. The hydrogen gas from the first gas supply source 28a may not be supplied into the chamber 26. Then, the process controller 23 controls the heater power supply 37 so as to set the temperature of the wafer W to a predetermined temperature. Thus, for example, as shown in FIG. 4C, carbon atoms solid-solved in the metal catalyst 51 are precipitated on the metal catalyst 51, and graphene 52 grows on the surface of the metal catalyst 51. The first growth process is an example of a first growth step.

The first growth process in step S104 is performed, for example, under the following processing conditions.

Gas flow rate ratio: Ar/H₂/C₂H₂=2200/0 to 2000/5 sccm

Pressure inside chamber 26: 1 Torr

Temperature of wafer W: 650 degrees C.

Processing time: 10 minutes

Next, the process controller 23 opens the gate valve 12c of the graphene producing module 13c and controls the transfer robot 19 so as to unload the wafer W subjected to the first growth process from the interior of the graphene producing module 13c. Then, the process controller 23 opens the gate valve 12d of the second heat treatment module 13d, controls the transfer robot 19 so as to mount the wafer W subjected to the first growth process on the mounting table 27 in the second heat treatment module 13d, and closes the gate valve 12d.

Next, the process controller 23 controls the second heat treatment module 13d so as to execute a third heat treatment on the wafer W (S105), More specifically, the process controller 23 controls the butterfly valve 42 and the vacuum pump 43 of the second heat treatment module 13d so as to depressurize the interior of the chamber 26 to a predetermined degree of vacuum. Then, the process controller 23 supplies the argon gas from the second gas supply source 28b and the oxygen gas from the third gas supply source 28c into the chamber 26 at predetermined flow rates, respectively, via the shower plate 38. Then, the process controller 23 controls the heater power supply 37 so as to set the temperature of the wafer W to a predetermined temperature. Thus, for example, as shown in FIG. 4D, excess carbon adhering to the surface of the metal catalyst 51 is removed. The third heat treatment is an example of an activation step.

The third heat treatment in step S105 is performed, for example, under the following processing conditions.

Gas flow rate ratio: Ar/O₂=1900/100 sccm

Pressure inside chamber 26: 1 Torr

Temperature of wafer W: 200 to 400 degrees C.

Treatment time: 10 minutes

Next, the process controller 23 controls the second heat treatment module 13d so as to execute a fourth heat treatment on the water W (S106). More specifically, the process controller 23 controls the butterfly valve 42 and the vacuum pump 43 of the second heat treatment module 13d so as to depressurize the interior of the chamber 26 to a predetermined degree of vacuum. Then, the process controller 23 supplies the hydrogen gas from the first gas supply source 28a and the argon gas from the second gas supply source 28b into the chamber 26 at predetermined flow rates, respectively, via the shower plate 38. Then, the process controller 23 controls the heater power supply 37 so as to set the temperature of the wafer W to a predetermined temperature. As a result, the surface of the metal catalyst 51, which is excessively oxidized in the third heat treatment shown in step S105, is reduced. The fourth heat treatment performed in step 5106 is performed, for example, under the same conditions as the processing conditions of the second heat treatment. The fourth heat treatment is an example of a cleaning step.

Next, the process controller 23 opens the gate valve 12d of the second heat treatment module 13d and controls the transfer robot 19 so as to unload the wafer W subjected to the fourth heat treatment from the interior of the second heat treatment module 13d. The process controller 23 opens the gate valve 12c of the graphene producing module 13c, controls the transfer robot 19 so as to mount the wafer W, on which the fourth heat treatment is performed, on the mounting table 27 in the graphene producing module 13c, and closes the gate valve 12c.

Then, the process controller 23 controls the graphene producing module 13c so as to execute a second growth process for growing the graphene 52 on the metal catalyst 51 on the wafer W (S107). More specifically, the process controller 23 controls the butterfly valve 42 and the vacuum pump 43 of the graphene producing module 13c so as to depressurize the interior of the chamber 26 to a predetermined degree of vacuum. Then, the process controller 23 supplies the hydrogen gas from the first gas supply source 28a, the argon gas from the second gas supply source 28b and the acetylene gas from the third gas supply source 28c into the chamber 26 at predetermined flow rates, respectively, via the shower plate 38. The hydrogen gas from the first gas supply source 28a may not be supplied into the chamber 26. Then, the process controller 23 controls the heater power supply 37 to set the temperature of the wafer W to a predetermined temperature. Thus, for example, as shown in FIG. 4E. carbon atoms solid-solved in the metal catalyst 51 are precipitated on the metal catalyst 51, and the graphene 52 regrows on the surface of the metal catalyst 51. The second growth process is an example of a second growth step.

Next, the process controller 23 determines whether the value of the variable n is equal to or larger than a predetermined threshold value N (S108). The threshold value N is set to a value at which the grain size of the crystal of the graphene 52 growing on the metal catalyst 51 becomes a desired size. In the present embodiment, the threshold value N is, for example, 30. When the value of the variable n is smaller than the threshold value N (S108: No), the process controller 23 increases the value of the variable n by 1 (S109) and re-executes the process shown in step S105.

On the other hand, when the value of the variable n is equal to or larger than the threshold value N (S108: Yes), the process controller 23 opens the gate valve 12c of the graphene producing module 13c and controls the transfer robot 19 so as to unload the wafer W from the interior of the graphene producing module 13c. Then, the process controller 23 controls the transfer robot 19 so as to transfer the wafer W into the load lock module 17. Then, the process controller 23 controls the transfer robot 21 so as to transfer the wafer W from the interior of the load lock module 17 into the carrier 20. Thus, the operation shown in this flowchart is completed.

### [Grain Size of Crystal of Graphene]

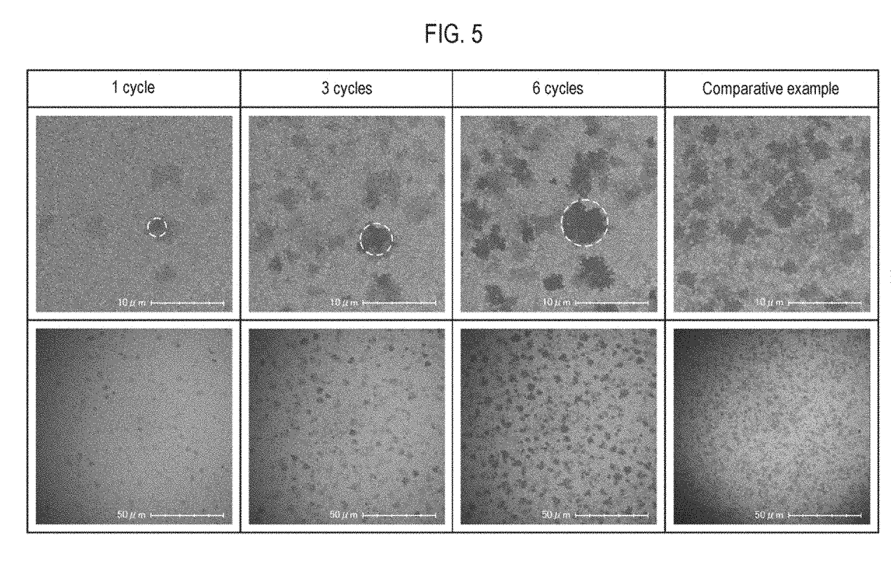

Herein, the relationship between the number of repetitions of the process shown in steps S105 to S109 of FIG. 3 and the grain size of the crystal of the graphene 52 will be described. FIG. 5 is a set of SEM photographs showing an example of a change in the grain size of the crystal of the graphene 52. In FIG. 5, as a comparative example, there is shown a SEM photograph of the graphene 52 in a case where the first growth process shown in step S104 of FIG. 3 is continuously performed for 60 minutes. The SEM photograph in the upper part of FIG. 5 shows the enlarged crystal of the graphene and its vicinity in the SEM photograph of the lower part of FIG. 5.

The term “1 cycle” shown in FIG. 5 indicates that the process of step S104 shown in FIG. 3 has been performed once. Furthermore, the term “3 cycles” shown in FIG. 5 indicates that, in addition to the process of step 5104 shown in FIG. 3, the process of steps 5105 to S109 shown in FIG. 3 has been repeated twice. In addition, the term “6 cycles” shown in FIG. 5 indicates that, in addition to the process of step S104 shown in FIG. 3, the process of steps S105 to 5109 shown in FIG. 3 has been repeated five times. During the 6 cycles, the first growth process shown in step S104 of FIG. 3 is performed once, and the second growth process shown in step S107 of FIG. 3 is repeated five times in total. In the present embodiment, the processing time of each of the first growth process and the second growth process is 10 minutes. Therefore, during the 6 cycles shown in FIG. 5, the processes of causing the graphene to grow (i.e., the first growth process and the second growth process) are performed for 60 minutes in total.

In the SEM photograph of the upper part of FIG. 5, the region surrounded by a broken line shows the region of the crystal of the graphene. As apparent from FIG. 5, the grain size of the graphene 52 is increased by repeating the process shown in steps S105 to S109 of FIG. 3 (i.e., by increasing the number of cycles). When the SEM photograph in the case where the process for causing the graphene to grow is performed by 6 cycles is compared with the SEM photograph in the comparative example, although the sum of the processing time of the process for growing the graphene is the same for each of the processes, it is known that the grain size of the crystal of the graphene is larger in the case where the process of growing the graphene is performed by 6 cycles than the grain size of the crystal of the graphene in the comparative example.

Incidentally, the graphene grows on the surface of the metal catalyst 51 as carbon atoms contained in a carbon-containing gas are solid-solved in the metal catalyst 51 and then precipitated on the surface of the metal catalyst. Since the interatomic distance of nickel constituting the metal catalyst 51 is long, when the metal catalyst 51 is exposed to the carbon-containing gas, carbon atoms are interposed between the atoms of nickel. As a result, the crystal structure of nickel as metal collapses, and the function as a catalyst of nickel deteriorates. Therefore, even if the process of growing graphene is simply continued, the function as a catalyst of nickel decreases due to the influence of the carbon atoms that have been interposed between the atoms of nickel. The growth of the graphene finally stops. For that reason, even if the process of growing the graphene is simply continued, it is difficult to obtain graphene having a large grain size.

On the other hand, in the graphene producing method according to the present embodiment, after the graphene 52 grows on the surface of the metal catalyst 51 for a predetermined time in the first growth process, the third heat treatment for thermally treating the surface of the metal catalyst 51 is performed using a mixed gas containing an oxygen gas. As a result, on the surface of the metal catalyst 51, it is possible to remove (etch) excessive carbon atoms interposed between the atoms of nickel as the metal catalyst 51 and not forming the graphene 52. This makes it possible to restore the function of the metal catalyst 51 as a catalyst (reactivate the metal catalyst 51) on the surface of the metal catalyst 51. Thus, the graphene 52 can grow again using the metal catalyst 51, and the graphene 52 having a large grain size can be formed.

In the present embodiment, the graphene producing module 13c in which the first growth process and the second growth process are performed, and the second heat treatment module 13d in Which the third and fourth heat treatments are performed, are configured by different processing modules 13. Therefore, the temperature of the wafer W is lowered to room temperature while the wafer W on which the graphene is formed in the graphene producing module 13c is transferred into the second heat treatment module 13d and while the wafer W subjected to the third heat treatment in the second heat treatment module 13d is transferred into the graphene producing module 13c. However, even in that case, by performing the third heat treatment before the second growth process, the function as a catalyst of the metal catalyst 51 is restored. As a result, even after the temperature of the wafer W returns to room temperature, it is possible to regrow the graphene in the second growth process. Therefore, even when the graphene producing module 13c and the second heat treatment module 13d are configured by different processing modules 13, it is possible to produce the graphene 52 having a large crystal grain size and to increase the degree of freedom of the apparatus configuration when forming the graphene 52 having a large crystal grain size. As another embodiment, the graphene producing module 13c and the second heat treatment module 13d may be realized by one processing module 13. This makes it possible to reduce the standby time associated with the repetition of the third heat treatment, the fourth heat treatment and the second growth process, thereby improving the throughput of the treatment or process.

### [Film Quality of Graphene]

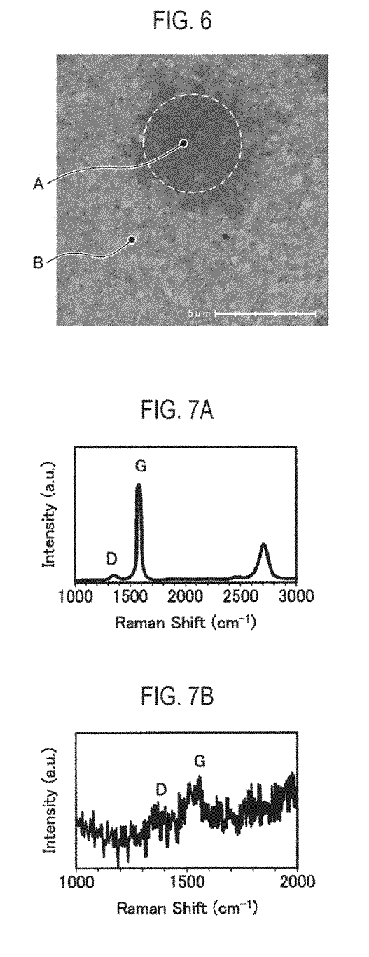

FIG. 6 is an SEM photograph showing an example of the surface of the graphene after the first growth process. On the surface of the metal catalyst 51, for example, the crystal of the graphene 52 is formed in a region surrounded by a broken line in FIG. 6. On the surface of the metal catalyst 51, for example, surplus carbon atoms not constituting the graphene 52 adhere to the vicinity of the region surrounded by the broken line in FIG. 6.

FIGS. 7A and 7B are diagrams showing examples of a distribution of the Raman spectrum. FIG. 7A shows an example of a distribution of the Raman spectrum at point A in FIG. 6, that is, at the position of the crystal of graphene on the surface of the metal catalyst 51. On the other hand, FIG. 7B shows an example of a distribution of the Raman spectrum at point B in FIG. 6, that is, at the position around the crystal of graphene on the surface of the metal catalyst 51. In this regard, which is a ratio of a peak I_{D} of a D band (a peak caused by a defective structure in the graphene) and a peak I_{G} of a G band (a peak caused by the in-plane vibration of the graphene) in the distribution of the Raman spectrum, is one of the indices representing the film quality of the graphene. The higher the value of I_{G}/I_{D}, the better the film quality of the graphene.

In FIG. 7A showing the distribution of the Raman spectrum at point A in FIG. 6, the value of I_{G}/I_{D} is 17. On the other hand, in FIG. 7B showing the distribution of the Raman spectrum at point B in FIG. 6, the value of I_{G}/I_{D} is 2.

FIG. 8 is an SEM photograph showing an example of the surface of the graphene after the third heat treatment. Even after the third heat treatment shown in step S105 of FIG. 3 is performed, the crystal of the graphene 52 remains on the surface of the metal catalyst 51, for example, in a region surrounded by a broken line in FIG. 8. On the other hand, on the surface of the metal catalyst 51, for example, surplus carbon atoms remaining around the region surrounded by the broken line in FIG. 8 and not constituting the graphene 52 are reduced by the third heat treatment.

In FIG. 8, the processing conditions of the third heat treatment performed on the wafer W on which the graphene is formed are, for example, as follows.

Gas flow rate ratio: Ar/O₂=1900/100 sccm

Pressure inside chamber 26: 1 Torr

Temperature of wafer W: 300 degrees C.

Processing time: 10 minutes

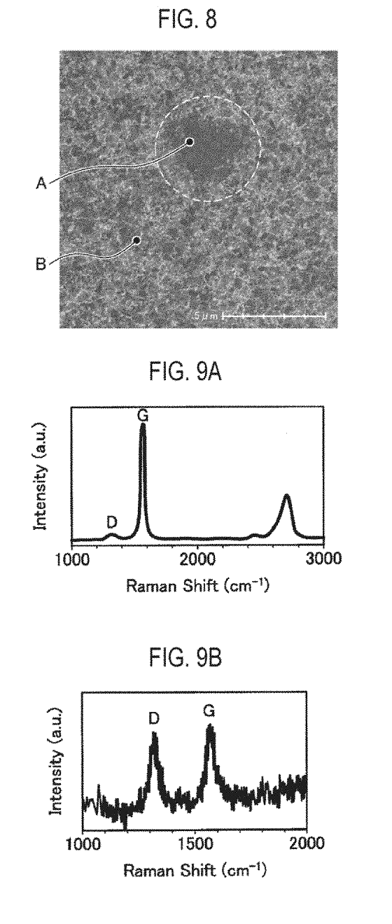

FIGS. 9A and 9B are diagrams showing examples of a distribution of the Raman spectrum. FIG. 9A shows an example of a distribution of the Raman spectrum at point A in FIG. 8, that is, at the position of the crystal of the graphene on the surface of the metal catalyst 51. On the other hand, FIG. 9B shows an example of a distribution of the Raman spectrum at point B in FIG. 8, that is, at the position around the crystal of the graphene on the surface of the metal catalyst 51.

In FIG. 9A showing the distribution of the Raman spectrum at point A in FIG. 8, the value of I_{G}/I_{D} is 22. Since the value of I_{G}/I_{D} at the position of the crystal of the graphene before the third heat treatment is 17, even if the third heat treatment is performed, the value of I_{G}/I_{D} at the position of the crystal of the graphene is kept high. Therefore, it was found that even when the third heat treatment is performed between the processes of growing the graphene (i.e., the first growth process and the second growth process), the quality of the crystal of the graphene hardly deteriorates.

On the other hand, in FIG. 9B showing the distribution of the Raman spectrum at point B in FIG. 8, the value of I_{G}/I_{D} is approximately 1. Since the value of I_{G}/I_{D} in the vicinity of the crystal of the graphene before the third heat treatment is 2, by performing the third heat treatment, the quality of the graphene deteriorates in the region where no graphene crystal is formed. This is probably because surplus graphene nuclei are etched and removed.

In this manner, by performing the third heat treatment between the processes of growing the graphene (i.e., between the first growth process and the second growth process and between the second growth processes repeatedly performed), it is possible to remove surplus carbon atoms other than the graphene crystal from the surface of the metal catalyst 51 without causing the quality of the graphene crystal to deteriorate and to reactivate the function as a catalyst of the metal catalyst 51. As a result, it is possible to regrow the graphene using the reactivated metal catalyst 51.

In the experiments shown in FIGS. 8 and 9, the temperature of the wafer W was set at 300 degrees C. If the temperature of the wafer W is too high, damage to the crystal of the graphene occurs and the quality of the crystal of the graphene deteriorates. On the other hand, if the temperature of the wafer W is too low, surplus carbon atoms adhering to the surface of the metal catalyst 51 are not sufficiently removed and the function as a catalyst of the metal catalyst 51 is not restored. Therefore, the treatment temperature in the third heat treatment is preferably in a range of 200 degrees C. to 400 degrees C.

The graphene producing method according to the embodiment has been described above. As is apparent from the foregoing description, the graphene producing method according to the present embodiment includes the first growth process, the third heat treatment and the second growth process. In the first growth process, the graphene 52 grows on the surface of the metal catalyst 51 by supplying the carbon-containing gas into the chamber 26 in which the metal catalyst 51 is disposed. In the third heat treatment, the metal catalyst 51 is reactivated by supplying a process gas containing an oxygen gas into the chamber 26 in which the metal catalyst 51 having the graphene 52 growing on the surface thereof is disposed. In the second growth process, the carbon-containing gas is supplied into the chamber 26 in which the reactivated metal catalyst 51 is disposed, thereby regrowing the graphene 52 on the surface of the metal catalyst 51. Thus, it is possible to produce graphene having a large grain size.

### [Others]

The present disclosure is not limited to the above-described embodiment. Various modifications may be made without departing from the spirit of the present disclosure.

For example, the second heat treatment shown in step S103 in FIG. 3 and the fourth heat treatment shown in step S106 may not be necessary.

In the above-described embodiment, nickel is used as the metal catalyst 51. However, the disclosed technique is not limited thereto. As the metal catalyst 51, in addition to nickel, it may be possible to use, for example, cobalt (Co), iron (Fe), copper (Cu), tungsten (W), or an alloy containing two or more of these metals. Moreover, as the metal catalyst 51, in addition to nickel, cobalt, iron, copper and tungsten, it may be possible to use a transition metal such as ruthenium (Ru), rhodium (Rh), silver (Ag), palladium (Pd), rhenium (Re), iridium (Ir), Platinum (Pt), gold (Au) or the like, or an alloy containing two or more of these metals.

In the third heat treatment shown in step S105 of FIG. 3, the mixed gas of an argon gas and an oxygen gas is used. However, the disclosed technique is not limited thereto. In the third heat treatment shown in step S105 of FIG. 3, for example, a mixed gas of an argon gas and a hydrogen gas may be used.

Furthermore, in the third heat treatment shown in step S105 of FIG. 3, surplus carbon atoms adhering to the surface of the metal catalyst 51 are removed by the heat treatment using the process gas containing an oxygen gas. However, the disclosed technique is not limited thereto. In step S105 of FIG. 3, surplus carbon atoms adhering to the surface of the metal catalyst 51 may be removed by using the plasma of the process gas containing an oxygen gas. In this case, it is preferred that the plasma of the process gas containing an oxygen gas is generated in a plasma generation chamber which is a space different from the processing space in the chamber 26 in which the wafer W is disposed, and the generated plasma is supplied into the processing space in which the wafer W is disposed. As a result, it is possible to reduce the damage to the graphene otherwise caused by the plasma.

According to various aspects and embodiments of the present disclosure, it is possible to produce graphene having a large grain size.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for producing graphene, comprising:
a first growth step of supplying a carbon-containing gas into a chamber in which a metal catalyst is disposed to grow graphene on a surface of the metal catalyst;
an activation step of supplying a process gas containing an oxygen gas or a hydrogen gas into the chamber in which the metal catalyst having the graphene grown on the surface thereof is disposed to reactivate the metal catalyst; and
a second growth step of supplying the carbon-containing gas into the chamber in which the reactivated metal catalyst is disposed to regrow the graphene on the surface of the metal catalyst.

2. The method of claim 1, further comprising:
between the activation step and the second growth step, a cleaning step of cleaning the surface of the metal catalyst by a process gas containing a hydrogen gas.

3. The method of claim 1, wherein the metal catalyst is a transition metal or an alloy containing two or more transition metals.

4. The method of claim 1, wherein the metal catalyst is Ni, Co, Fe, Cu, W, or an alloy containing two or more of Ni, Co, Fe, Cu and W.

5. The method of claim 1, wherein the activation step is performed by using a process gas containing an oxygen gas and an inert gas under a condition in which the temperature of the metal catalyst falls in a temperature range of 200 degrees C. or higher and 400 degrees C. or lower.

6. The method of claim 1, wherein the activation step and the second growth step is performed alternately and repeatedly.
